(19) United States
(12) Patent Application Publication
(10) Pub. No.: US 2022/0328391 A1
(43) Pub. Date: Oct. 13, 2022

(54) SEMICONDUCTOR SUBSTRATE AND MANUFACTURING METHOD THEREOF AND SEMICONDUCTOR PACKAGE STRUCTURE

(71) Applicant: Dyi-Chung HU, Hsinchu (TW)

(72) Inventor: Dyi-Chung HU, Hsinchu (TW)

(21) Appl. No.: 17/715,045

(22) Filed: Apr. 7, 2022

Related U.S. Application Data
(60) Provisional application No. 63/172,637, filed on Apr. 8, 2021.
(60) Provisional application No. 63/176,897, filed on Apr. 20, 2021.

(30) Foreign Application Priority Data
Dec. 23, 2021 (TW) 110148369

(51) Int. Cl. H01L 23/498; H01L 25/065; H01L 23/00; H01L 21/48

(52) U.S. Cl. CPC H01L 23/49822; H01L 25/0655; H01L 24/16; H01L 23/49816; H01L 23/49833; H01L 21/4857; H01L 21/486; H01L 24/73; H01L 24/32; H01L 2224/32225; H01L 2224/73204; H01L 2224/16227; H01L 2224/16238; H01L 2924/3511

(57) ABSTRACT

A semiconductor substrate includes a first thin film redistribution layer, multiple first connecting members, a second thin film redistribution layer, multiple second connecting members, and multiple solder balls. The first connecting members and the chip are respectively disposed on a first and a second surfaces of the first thin film redistribution layer. The second connecting members and the solder balls are respectively disposed on a third and a fourth surfaces of the second thin film redistribution layer. The second connecting members are respectively connected to the first connecting members, so that the second thin film redistribution layer is bonded to the first thin film redistribution layer.

### CROSS-REFERENCE TO RELATED APPLICATION

This application claims the priority benefit of U.S. provisional application Ser. No. 63/172,637, filed on Apr. 8, 2021, U.S. provisional application Ser. No. 63/176,897, filed on Apr. 20, 2021, and Taiwan application serial no. 110148369, filed on Dec. 23, 2021. The entirety of each of the above-mentioned patent applications is hereby incorporated by reference herein and made a part of this specification.

### BACKGROUND

### Technical Field

The disclosure relates to a substrate and a manufacturing method thereof, and more particularly, to a semiconductor substrate and a manufacturing method thereof and a semiconductor package structure using the semiconductor substrate.

### Description of Related Art

Multilayer thin film redistribution layers are usually used as part of high-end heterogeneous integration substrates. Usually, the thin film redistribution layers are processed on a temporary glass carrier. As thin film layers are building up, the high stress in the thin film layers will cause severe warpage of the thin film layers on the glass carrier. That prevents the further building of the thin film layers. Hence currently, only two or three metal layers with two or three dielectric layers may be disposed on the glass carrier. That is to say, the circuit layer in the thin film redistribution layer may not exceed three layers. That restricts the application range of the thin film redistribution layer and may not satisfy the needs of heterogeneous integration substrate for more complex systems.

### SUMMARY

The disclosure provides a semiconductor substrate and a manufacturing method thereof and a semiconductor package structure, which may have a multilayer thin film redistribution layer with three or more layers, and with good manufacturability.

A semiconductor substrate in the disclosure includes a first thin film redistribution layer, multiple first connecting members, a second thin film redistribution layer, and multiple second connecting members. The first thin film redistribution layer has a first surface and a second surface opposite to each other. The first connecting members are disposed on the first surface of the first thin film redistribution layer. The second thin film redistribution layer has a third surface and a fourth surface opposite to each other. The second connecting members are disposed on the third surface of the second thin film redistribution layer. The second connecting members are respectively connected to the first connecting members, so that the second thin film redistribution layer is bonded to the first thin film redistribution layer.

In an embodiment of the disclosure, the semiconductor substrate further includes a filling glue layer filled between the first thin film redistribution layer and the second thin film redistribution layer, and covering the first connecting members and the second connecting members.

In an embodiment of the disclosure, the number of layers of the first thin film redistribution layer is close to the number of layers of the second thin film redistribution layer, and the number of layers of the first thin film redistribution layer is one layer more than the number of layers of the second thin film redistribution layer.

In an embodiment of the disclosure, the number of layers of the first thin film redistribution layer is the same as the number of layers of the second thin film redistribution layer. The same number of layers for the first and the second thin film redistribution layer will significantly reduce the warpage after bonding of the two thin film redistribution layers.

In an embodiment of the disclosure, a coefficient of thermal expansion of the first thin film redistribution layer is the same as or similar to a coefficient of thermal expansion of the second thin film redistribution layer. The similar thermal expansion coefficient of the first and second thin film redistribution layers will reduce the warpage of the two thin film redistribution layers.

In an embodiment of the disclosure, the semiconductor package structure further includes multiple connecting pads and a solder mask layer. The connecting pads are disposed on the fourth surface of the second thin film redistribution layer, and are electrically connected to the second thin film redistribution layer. The solder mask layer is disposed on the fourth surface of the second thin film redistribution layer, and has multiple openings. The openings expose a part of the connecting pads.

In an embodiment of the disclosure, the first thin film redistribution layer comprises a plurality of first conductive vias, and the second thin film redistribution layer comprises a plurality of second conductive vias. A via tapered direction of each of the first conductive vias is in opposite direction of a via tapered direction of each of the second conductive vias. The via taper direction is caused by the first and second thin film redistribution layers being processed on a carrier.

In an embodiment of the disclosure, a wiring density of the first thin film redistribution layer is higher than a wiring density of the second thin film redistribution layer.

In an embodiment of the disclosure, the first thin film redistribution layer includes multilayer first redistribution circuit layers and a first retaining ring surrounding the first redistribution circuit layers. The second thin film redistribution layer includes multilayer second redistribution circuit layers and a second retaining ring surrounding the second redistribution circuit layers. The first retaining ring and the second retaining ring are connected to each other through the first connecting members and the second connecting members.

In an embodiment of the disclosure, the mostly pad pitch of the second surface of the first thin film redistribution layer is finer than the mostly pad pitch of the fourth surface of the second thin film redistribution layer. The finer pitch is required to connect dies on top of the fine pitch.

A manufacturing method of a semiconductor package structure in the disclosure includes the following steps. A first thin film redistribution layer is formed on a first carrier. A first release film is disposed on the first carrier, and the first thin film redistribution layer has a first surface and a second surface opposite to each other. The first release film is located between the second surface of the first thin film redistribution layer and the first carrier. Multiple first connecting members are formed on the first surface of the first thin film redistribution layer. A second thin film redistribution layer is form on a second carrier. A second release film is disposed on the second carrier, and the second thin film redistribution layer has a third surface and a fourth surface opposite to each other. The second release film is located between the fourth surface of the second thin film redistribution layer and the second carrier. Multiple second connecting members are formed on the third surface of the second thin film redistribution layer. The second connecting members are connected to the first connecting members, so that the second thin film redistribution layer is bonded to the first thin film redistribution layer. The first carrier and the first release film are removed, and the second surface of the first thin film redistribution layer is exposed. The second carrier and the second release film are removed, and the fourth surface of the second thin film redistribution layer is exposed.

In an embodiment of the disclosure, the manufacturing method of the semiconductor package structure further includes the following. After the second carrier and the second release film are removed, multiple connecting pads separated from one another are formed on the fourth surface of the second thin film redistribution layer. The connecting pads are electrically connected to the second thin film redistribution layer. A solder mask layer is formed on the fourth surface of the second thin film redistribution layer. The solder mask layer has multiple openings to expose a part of the connecting pads.

In an embodiment of the disclosure, the number of layers of the first thin film redistribution layer is different from the number of layers of the second thin film redistribution layer. The number of layers of the first thin film redistribution layer is one layer more than the number of layers of the second thin film redistribution layer.

In an embodiment of the disclosure, the number of layers of the first thin film redistribution layer is the same as the number of layers of the second thin film redistribution layer.

In an embodiment of the disclosure, the first thin film redistribution layer comprises a plurality of first conductive vias, and the second thin film redistribution layer comprises a plurality of second conductive vias. A via tapered direction of each of the first conductive vias is in opposite direction of a via tapered direction of each of the second conductive vias.

In an embodiment of the disclosure, a wiring density of the first thin film redistribution layer is higher than a wiring density of the second thin film redistribution layer.

In an embodiment of the disclosure, the first thin film redistribution layer includes multilayer first redistribution circuit layers and a first retaining ring surrounding the first redistribution circuit layers. The second thin film redistribution layer includes multilayer second redistribution circuit layers and a second retaining ring surrounding the second redistribution circuit layers. The first retaining ring and the second retaining ring are connected to each other through the first connecting members and the second connecting members.

A semiconductor package structure in the disclosure includes a first thin film redistribution layer, multiple first connecting members, a second thin film redistribution layer, multiple second connecting members, a chip, and multiple solder balls. The first thin film redistribution layer has a first surface and a second surface opposite to each other. The first connecting members are disposed on the first surface of the first thin film redistribution layer. The second thin film redistribution layer has a third surface and a fourth surface opposite to each other. The second connecting members are disposed on the third surface of the second thin film redistribution layer. The second connecting members are respectively connected to the first connecting members, so that the second thin film redistribution layer is bonded to the first thin film redistribution layer. The chip is disposed on the second surface of the first thin film redistribution layer. The solder balls are disposed on the fourth surface of the second thin film redistribution layer.

In an embodiment of the disclosure, the semiconductor package structure further includes a filling glue layer, filled between the first thin film redistribution layer and the second thin film redistribution layer, and covers the first connecting members and the second connecting members.

In an embodiment of the disclosure, the semiconductor package structure further includes multiple third connecting members disposed on the second surface of the first thin film redistribution layer. The chip has an active surface and a back surface opposite to each other, and a peripheral surface connecting the active surface and the back surface, and the chip includes multiple fourth connecting members disposed on the active surface. The fourth connecting members are respectively connected to the third connecting members, so that the chip is bonded to the first thin film redistribution layer.

In an embodiment of the disclosure, each of the third connecting members includes a pad and a conductive pillar. The pad is disposed on the second surface of the first thin film redistribution layer, and the conductive pillar is located between the pad and each of the fourth connecting members of the chip.

In an embodiment of the disclosure, the semiconductor package structure further includes a molding compound covering the third connecting members, the fourth connecting members, and the active surface, the back surface, and the peripheral surface of the chip. An edge of the molding compound is flush with an edge of the filling glue layer.

In an embodiment of the disclosure, the semiconductor package structure further includes an underfill covering the third connecting members, the fourth connecting members, and the active surface of the chip and exposing the back surface and the peripheral surface of the chip.

In an embodiment of the disclosure, the number of layers of the first thin film redistribution layer is different from the number of layers of the second thin film redistribution layer.

In an embodiment of the disclosure, the number of layers of the first thin film redistribution layer is the same as the number of layers of the second thin film redistribution layer.

In an embodiment of the disclosure, the semiconductor package structure further includes multiple connecting pads and a solder mask layer. The connecting pads are disposed on the fourth surface of the second thin film redistribution layer, and are electrically connected to the second thin film redistribution layer. The solder mask layer is disposed on the fourth surface of the second thin film redistribution layer, and has multiple openings. The openings expose a part of the connecting pads, and the solder balls are respectively located in the openings and connected to the connecting pads exposed by the openings.

In an embodiment of the disclosure, an extending direction of each of the first connecting members is opposite to an extending direction of each of the second connecting members.

In an embodiment of the disclosure, a wiring density of the first thin film redistribution layer is higher than a wiring density of the second thin film redistribution layer.

In an embodiment of the disclosure, the first thin film redistribution layer includes multilayer first redistribution circuit layers and a first retaining ring surrounding the first redistribution circuit layers. The second thin film redistribution layer includes multilayer second redistribution circuit layers and a second retaining ring surrounding the second redistribution circuit layers. The first retaining ring and the second retaining ring are connected to each other through the first connecting members and the second connecting members.

Based on the above, in the design of the semiconductor substrate and manufacturing method thereof in the disclosure, the second connecting members located on the second thin film redistribution layer are respectively connected to the first connecting members located on the first thin film redistribution layer, so that the second thin film redistribution layer is bonded to the first thin film redistribution layer. In this way, the multilayer thin film redistributions layer with at least three or more layers may be formed, and with good manufacturability.

In order for the aforementioned features and advantages of the disclosure to be more comprehensible, embodiments accompanied with drawings are described in detail below.

### BRIEF DESCRIPTION OF THE DRAWINGS

FIGS. 1A to 1F are schematic cross-sectional views of a manufacturing method of a semiconductor substrate according to an embodiment of the disclosure.

FIG. 2 is a schematic cross-sectional view of a semiconductor substrate according to another embodiment of the disclosure.

FIGS. 3A to 3G are schematic cross-sectional views of some steps of a manufacturing method of a semiconductor package structure according to an embodiment of the disclosure.

FIGS. 4A to 4F are schematic cross-sectional views of some steps of a manufacturing method of a semiconductor package structure according to another embodiment of the disclosure.

FIG. 5 is a schematic cross-sectional view of a semiconductor package structure according to an embodiment of the disclosure.

FIG. 6 is a schematic cross-sectional view of a semiconductor package structure according to another embodiment of the disclosure.

FIG. 7 is a schematic cross-sectional view of a semiconductor package structure according to another embodiment of the disclosure.

FIG. 8 is a schematic cross-sectional view of a semiconductor package structure according to another embodiment of the disclosure.

FIG. 9 is a schematic cross-sectional view of a semiconductor package structure according to another embodiment of the disclosure.

### DETAILED DESCRIPTION OF DISCLOSED EMBODIMENTS

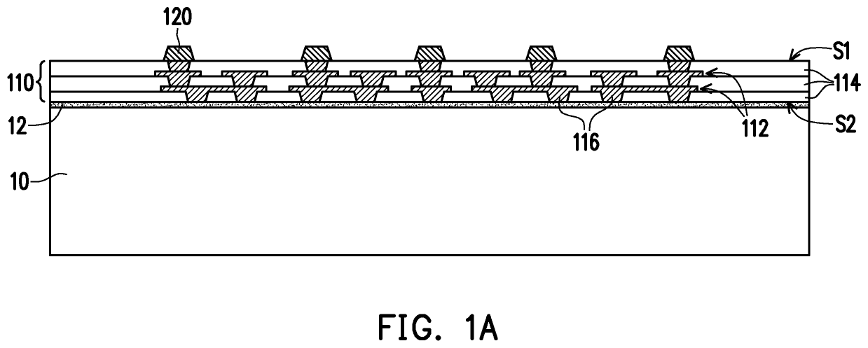

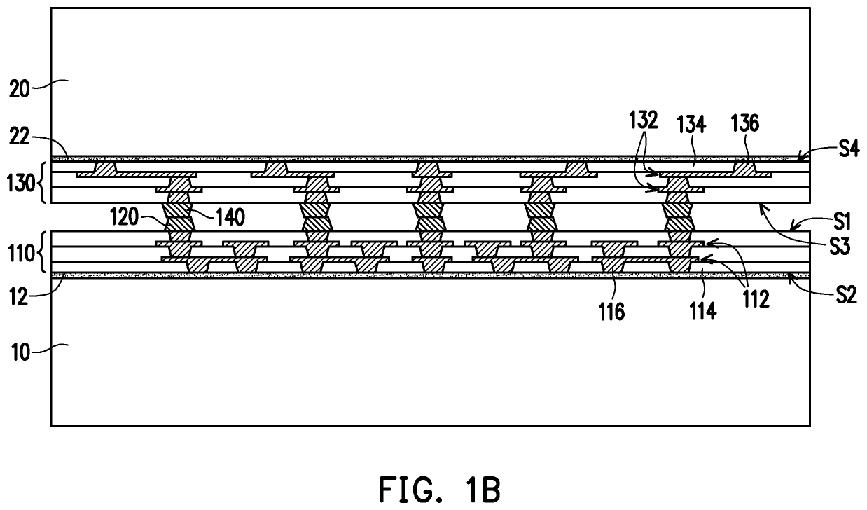

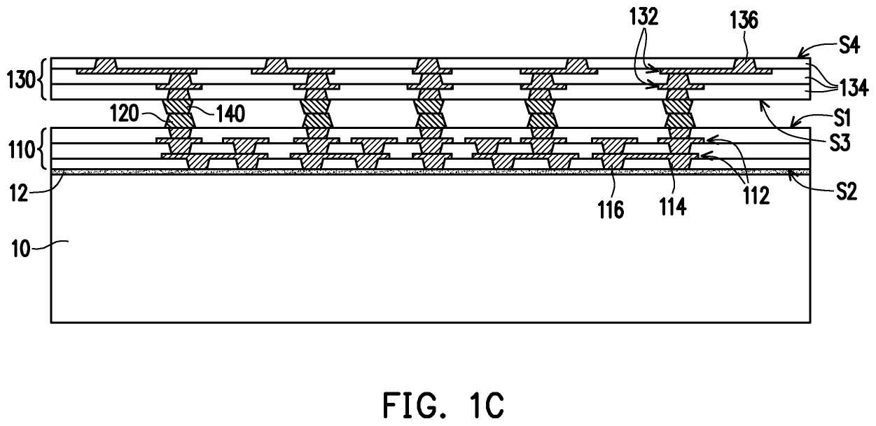

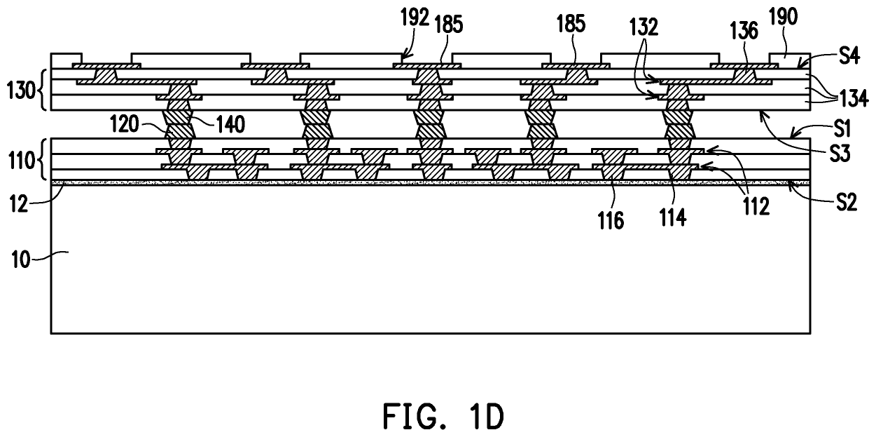

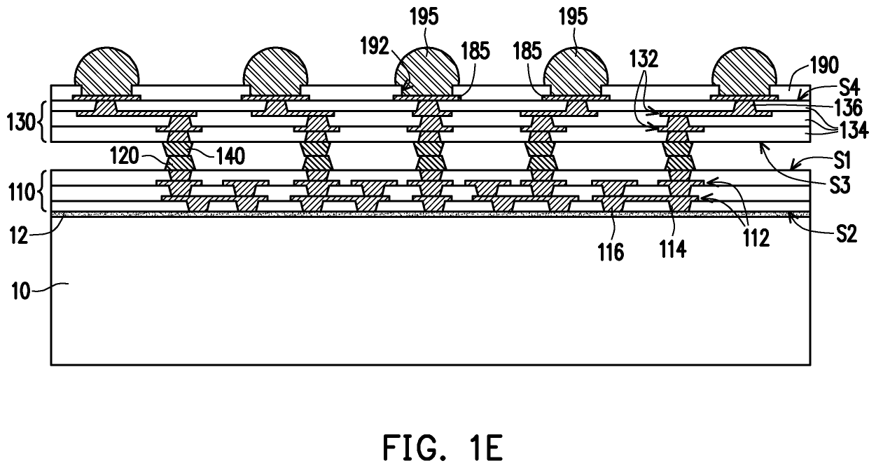

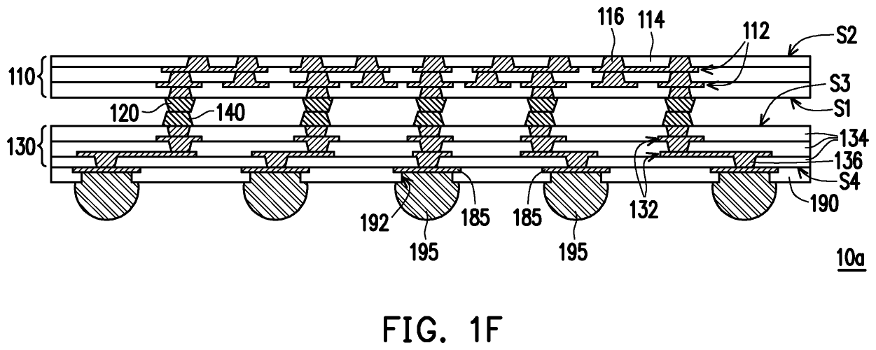

FIGS. 1A to 1F are schematic cross-sectional views of a manufacturing method of a semiconductor substrate according to an embodiment of the disclosure. Regarding the manufacturing method of the semiconductor substrate in this embodiment, first, referring to FIG. 1A, a first thin film redistribution layer 110 is formed on a first carrier 10. A first release film 12 is disposed on the first carrier 10, and the first thin film redistribution layer 110 has a first surface S1 and a second surface S2 opposite to each other. The first release film 12 is located between the second surface S2 of the first thin film redistribution layer 110 and the first carrier 10.

In detail, in this embodiment, the first carrier 10 is, for example, a temporary substrate. A material of the first carrier 10 may be formed by glass, plastic, silicon, metal, or other suitable materials, as long as the material may carry a structure formed thereon in a subsequent manufacturing process. In some embodiments, the first release film 12 (for example, a light to heat conversion film or other suitable de-bonding layers) applied on the first carrier 10 may increase releasibility of the subsequently formed structure from the first carrier 10 in a subsequent de-bonding process. Optionally, the first release film 12 may be omitted.

As shown in FIG. 1A, the first thin film redistribution layer 110 may be formed on the first carrier 10. The first thin film redistribution layer 110 includes multilayer first redistribution circuit layers 112 (in which two layers of the first redistribution circuit layers 112 are schematically shown), multilayer first dielectric layers 114 (in which three layers of the first dielectric layers 114 are schematically shown), and multiple first conductive vias 116. The first redistribution circuit layer 112 and the first conductive vias 116 buried in the first dielectric layer 114 may be collectively regarded as a fine redistribution circuitry of the first thin film redistribution layer 110.

In some embodiments, materials of the first redistribution circuit layer 112 and the first conductive via 116 may be or may include copper, gold, nickel, aluminum, platinum, tin, a metal alloy, a combination thereof, or other suitable conductive materials. The first dielectric layers 114 are stacked on one another, and a material of the first dielectric layer 114 may be or may include polyimide (PI), benzocyclobutene (BCB), polybenzoxazole (PBO), an inorganic dielectric material (for example, silicon oxide and silicon nitride, etc.) or other suitable electrical insulating materials.

In some embodiments, a metallic deposition process, a lithography and etching process, or other suitable techniques may be used to form the first redistribution circuit layer 112 on the first carrier 10. In some embodiments, the first redistribution circuit layer 112 near a level of a bottom of the first carrier 10 includes multiple conductive pads (not shown) for a subsequent element-mounting process. Next, for example, a coating process, the lithography and etching process, or other suitable techniques may be used to form the first dielectric layer 114 having an opening above the first carrier 10, so as to cover the first redistribution circuit layer 112. The opening of the first dielectric layer 114 may expose at least a part of the first redistribution circuit layer 112 for further electrical connection. Optionally, the first dielectric layer 114 is formed before the first redistribution circuit layer 112 is formed. Subsequently, plating, deposition, or other suitable processes may be used to form the conductive material in the opening of the first dielectric layer 114, so as to form the first conductive via 116. The term “conductive via” may be an element that provides vertical electrical connection between layers and penetrates a plane of one or more adjacent layers. When the conductive material is formed in the opening, the conductive material may also be formed on a top surface of the first dielectric layer 114. Then, the conductive material on the top surface of the first dielectric layer 114 is patterned to form another layer of the first redistribution circuit layer 112. The first redistribution circuit layer 112 on the top surface of the first dielectric layer 114 may include a conductive line and a pad. The first redistribution circuit layer 112 may be referred to as a patterned conductive layer having a fine line/space wiring.

The above steps may be repeatedly performed, so that the first redistribution circuit layers 112 and the first dielectric layers 114 are alternately stacked, and the first conductive vias 116 are buried in the first dielectric layers 114. The first conductive vias 116 may form the electrical connection and physical connection between the first redistribution circuit layers 112 in different layers. In some embodiments, the first thin film redistribution layer 110 is a stack of layers having fine line/space routing. It should be noted that the first thin film redistribution layer 110 shown in FIG. 1A is merely exemplary, and a redistribution structure with more layers or less layers may be formed according to requirements of the circuit design.

Continuing to refer to FIG. 1A, the first thin film redistribution layer 110 includes the first surface S1 and the second surface S2 opposite to each other. The second surface S2 faces the first carrier 10. The first conductive vias 116 and the first dielectric layer 114 on the second surface S2 of the first thin film redistribution layer 110 may be substantially flush with one another. In some embodiments, the first redistribution circuit layer 112 may be formed on the top surface of the uppermost first dielectric layer 114. In this case, the first surface S1 includes the first redistribution circuit layer 112 and the uppermost first dielectric layer 114. In some embodiments, the first conductive via 116 tapers toward the first carrier 10. A thickness of the first thin film redistribution layer 110 may be in a range of about 2 μm to about 10 μm. However, other values are also possible according to product requirements/process recipes.

Referring to FIG. 1A again, multiple first connecting members 120 are formed on the first surface S1 of the first thin film redistribution layer 110. The first connecting member 120 is, for example, a pillar portion formed on the first surface S1 of the first thin film redistribution layer 110. A diameter of the first connecting member 120 gradually decreases in a direction away from the first surface S1 , but the disclosure is not limited thereto. In another embodiment, the diameter of the first connecting member 120 may also gradually increase in the direction away from the first surface S 1. In this embodiment, the first connecting members 120 and the first conductive vias 116 may be formed by plating in the same step. Optionally, after the first thin film redistribution layer 110 is formed, the first connecting members 120 are separately formed (or placed on the first thin film redistribution layer 110). In some embodiments, a material of the first connecting member 120 includes copper, gold, nickel, aluminum, platinum, tin, a combination thereof, an alloy thereof, or another suitable conductive material. It should be noted that the number of the first connecting members 120 shown herein is only for illustrative purposes, and does not constitute a limitation to the disclosure.

Referring to FIG. 1B, a second thin film redistribution layer 130 is formed on a second carrier 20. A second release film 22 is disposed on the second carrier 20, and the second thin film redistribution layer 130 has a third surface S3 and a fourth surface S4 opposite to each other. The second release film 22 is located between the fourth surface S4 of the second thin film redistribution layer 130 and the second carrier 20. The fourth surface S4 faces the second carrier 20, and the second carrier 20 is, for example, a temporary substrate. The second thin film redistribution layer 130 includes multilayer second redistribution circuit layers 132 (in which two layers of the second redistribution circuit layers 132 are schematically shown), multilayer second dielectric layers 134 (in which three layers of the second dielectric layers 134 are schematically shown), and multiple second conductive vias 136.

It should be noted that materials of the second carrier 20 and the second release film 22 are the same as or similar to the materials of the first carrier 10 and the first release film 12, and a manufacturing method and a material of the second thin film redistribution layer 130 are the same as the manufacturing method and the material of the first thin film redistribution layer 110. Reference may be made to the descriptions of the first carrier 10, the first release film 12, and the first thin film redistribution layer 110. Thus, details in this regard will not be further reiterated in the following.

Referring to FIG. 1B again, multiple second connecting members 140 are formed on the third surface S3 of the second thin film redistribution layer 130. The second connecting member 140 is, for example, a pillar portion formed on the third surface S3 of the second thin film redistribution layer 130. A diameter of the second connecting member 140 gradually decreases in a direction away from the third surface S3, but the disclosure is not limited thereto. In another embodiment, the diameter of the second connecting member 140 may also gradually increase in the direction away from the third surface S3. In this embodiment, the second connecting members 140 and the second conductive vias 136 may be formed by plating in the same step. Optionally, after the second thin film redistribution layer 130 is formed, the second connecting members 140 are separately formed (or placed on the second thin film redistribution layer 130). In some embodiments, a material of the second connecting member 140 includes copper, gold, nickel, aluminum, platinum, tin, a combination thereof, an alloy thereof, or another suitable conductive material. It should be noted that the number of the second connecting members 140 shown herein is only for illustrative purposes, and does not constitute a limitation to the disclosure.

Continuing to refer to FIG. 1B, the third surface S3 of the second thin film redistribution layer 130 faces the first surface S1 of the first thin film redistribution layer 110, so that the second connecting members 140 are respectively connected to the first connecting members 120, and that the second thin film redistribution layer 130 is bonded to the first thin film redistribution layer 110. Here, the second connecting members 140 are structurally connected and electrically connected to the first connecting members 120. The second connecting members 140 may be connected to the first connecting members 120 in an aligned manner or in a staggered manner, and the disclosure is not limited thereto. The first thin film redistribution layer 110 is electrically connected to the second thin film redistribution layer 130 through the first connecting members 120 and the second connecting members 140. In some embodiments, the connection between the first connecting members 120 and the second connecting members 140 can be solder bonding, hybrid boning or copper to copper direct bonding, and the disclosure is not limited thereto.

Herein, the number of layers of the first thin film redistribution layer 110 (including the number of circuit layers and the number of dielectric layers) is the same as that of the second thin film redistribution layer 130, which means that the numbers of layers of the first thin film redistribution layer 110 and the second thin film redistribution layer 130 are symmetrical, but the disclosure is not limited thereto. A coefficient of thermal expansion of the first thin film redistribution layer 110 is the same as or similar to a coefficient of thermal expansion of the second thin film redistribution layer 130. In particular, a wiring density of the first thin film redistribution layer 110 is higher than that of the second thin film redistribution layer 130. Avia tapered direction of the second conductive via 136 is in opposite direction of a via tapered direction of the first conductive via 116. Optionally an extending direction of the first connecting member 120 (for example, from top to bottom) is opposite to an extending direction of the second connecting member 140 (for example, from bottom to top). However, the disclosure is not limited thereto.

Referring to both FIG. 1B and FIG. 1C, the second carrier 20 and the second release film 22 are removed, and the fourth surface S4 of the second thin film redistribution layer 130 is exposed.

Referring to FIG. 1D, the connecting pads 185 separated from one another are formed on the fourth surface S4 of the second thin film redistribution layer 130. The connecting pads 185 are located on the outermost second dielectric layer 134 of the second thin film redistribution layer 130, and are electrically connected to the second conductive vias 136 on the outermost side of the second thin film redistribution layer 130.

Referring to FIG. 1D again, the solder mask layer 190 is formed on the fourth surface S4 of the second thin film redistribution layer 130. The solder mask layer 190 is located on the outermost second dielectric layer 134 of the second thin film redistribution layer 130, and the solder mask layer 190 has the openings 192 to expose a part of the connecting pads 185.

Afterwards, referring to FIG. 1E, the solder balls 195 are disposed on the fourth surface S4 of the second thin film redistribution layer 130. The solder balls 195 are respectively located in the openings 192 of the solder mask layer 190, and are structurally and electrically connected to the connecting pads 185 exposed by the openings 192.

Finally, referring to both FIGS. 1E and 1F, the first carrier 10 and the first release film 12 are removed, and the second surface S2 of the first thin film redistribution layer 110 is exposed. After that, the overall structure is turned over and the manufacture of a semiconductor substrate 10a has been completed.

In terms of the structure, referring to FIG. 1F again, the semiconductor substrate 10a in this embodiment includes the first thin film redistribution layer 110, the first connecting members 120, the second thin film redistribution layer 130, the second connecting members 140, and the solder balls 195. The first thin film redistribution layer 110 has the first surface S1 and the second surface S2 opposite to each other, and includes two layers of the first redistribution circuit layers 112, three layers of the first dielectric layers 114, and the first conductive vias 116. The first connecting members 120 are disposed on the first surface S1 of the first thin film redistribution layer 110. The second thin film redistribution layer 130 has the third surface S3 and the fourth surface S4 opposite to each other, and includes two layers of the second redistribution circuit layers 132, three layers of the second dielectric layers 134, and the second conductive vias 136. The second connecting members 140 are disposed on the third surface S3 of the second thin film redistribution layer 130. The second connecting members 140 are respectively connected to the first connecting members 120, so that the second thin film redistribution layer 130 is bonded to the first thin film redistribution layer 110. Herein, the number of layers of the first redistribution circuit layer 112 is the same as the number of layers of the second redistribution circuit layer 132, and the number of layers of the first dielectric layer 114 is the same as the number of layers of the second dielectric layer 134. However, the disclosure is not limited thereto. The solder balls 195 are disposed on the fourth surface S4 of the second thin film redistribution layer 130.

Furthermore, in this embodiment, the semiconductor substrate 10a further includes the connecting pads 185 and the solder mask layer 190. The connecting pads 185 are disposed on the fourth surface S4 of the second thin film redistribution layer 130, and are structurally and electrically connected to the second conductive vias 136 on the outermost side of the second thin film redistribution layer 130. The solder mask layer 190 is disposed on the fourth surface S4 of the second thin film redistribution layer 130 and has the openings 192. The openings 192 expose a part of the connecting pads 185. The solder balls 195 are respectively located in the openings 192 of the solder mask layer 190, and are structurally and electrically connected to the connecting pads 185 exposed by the openings 192.

In brief, in a manufacturing method of the semiconductor substrate 10a in this embodiment, the second connecting members 140 located on the second thin film redistribution layer 130 are respectively connected to the first connecting members 120 located on the first thin film redistribution layer 110, so that the second thin film redistribution layer 130 is bonded to the first thin film redistribution layer 110. In this way, multilayer thin film redistribution layers with at least three or more layers are formed. Compared with the conventional thin film redistribution layer in which only the thin film redistribution layer with no more than three layers of circuits may be formed on a glass carrier, the manufacturing method of the semiconductor substrate 10a in this embodiment has an advantage of simple manufacturing process, and is not limited to the conventional technology in which only metal with two or three layers may be disposed on the glass carrier. Furthermore, in this embodiment, the first thin film redistribution layer 110 with the higher wiring density is bonded to the chip 170, and the second thin film redistribution layer 130 with the lower wiring density is bonded to the solder balls 195. In this way, a fan-out type circuit structure is formed. In addition, since the semiconductor substrate 10a in this embodiment may have the multilayer thin film redistribution layers with at least three or more layers, it may be applied and expanded to more complex systems.

It is noted that some of the reference numerals and descriptions of the above embodiment will apply to the following embodiments. The same reference numerals will represent the same or similar components and the descriptions of the same technical contents will be omitted. Reference may be made to the above embodiment for the omitted descriptions, which will not be repeated in the following embodiments.

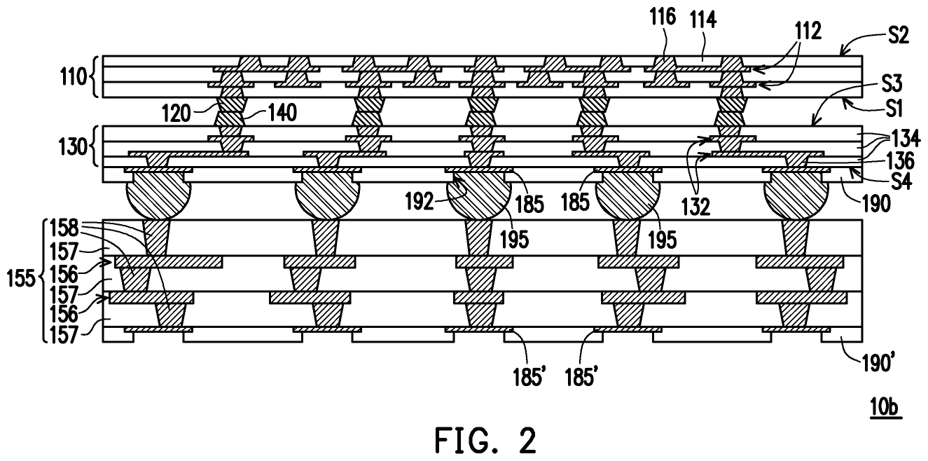

FIG. 2 is a schematic cross-sectional view of a semiconductor substrate according to another embodiment of the disclosure. Referring to both FIGS. 1F and 2, a semiconductor substrate 10b in this embodiment is similar to the semiconductor substrate 10a in FIG. 1F. A difference between the two is that in this embodiment, the semiconductor substrate 10b further includes a redistribution structure layer 155. In detail, the redistribution structure layer 155 includes multilayer third redistribution circuit layers 156 (in which two layers of the third redistribution circuit layers 156 are schematically shown), multilayer third dielectric layers 157 (in which three layers of the third dielectric layers 157 are schematically shown), and multiple third conductive vias 158. The third redistribution circuit layers 156 and the third dielectric layers 157 are alternately stacked, and the third redistribution circuit layers 156 are electrically connected through the third conductive vias 158. Here, a thickness of each of the third dielectric layers 157 is greater than a thickness of each of the second dielectric layers 134 and a thickness of each of the first dielectric layers 114d. A material of the third dielectric layer 157 is, for example, prepreg (PP) or Ajinomoto build up film (ABF), but the disclosure is not limited thereto. Then, a solder mask layer 190′ is formed on the lower surface of the redistribution structure layer 155. The solder mask layer 190′ is located on the outermost third dielectric layer 157 and has multiple openings, so as to expose a part of each of the connecting pads 185′.

In addition, optionally, the filling glue layer can cover the first connecting members 120 and the second connecting members 140 for protection. Optionally, the connection between the first connecting members 120 and the second connecting members 140 can be solder bonding, hybrid boning or copper to copper direct bonding, and the disclosure is not limited thereto. A wiring density of the first thin film redistribution layer 110 and a wiring density of the second thin film redistribution layer 130 are higher than that of the redistribution structure layer 155. A line width and a line pitch of the third redistribution circuit layer 156 are greater than a line width and a line pitch of the first redistribution line circuit 112 and a line width and a line pitch of the second redistribution circuit layer 132.

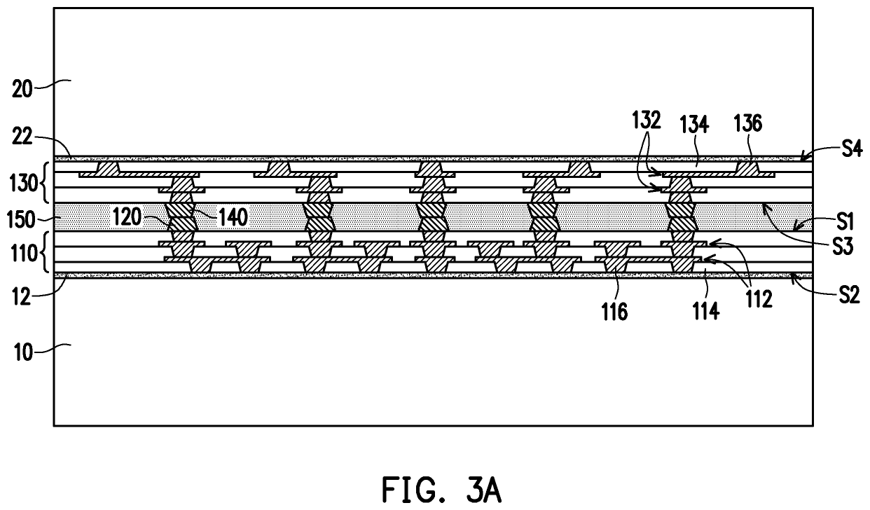

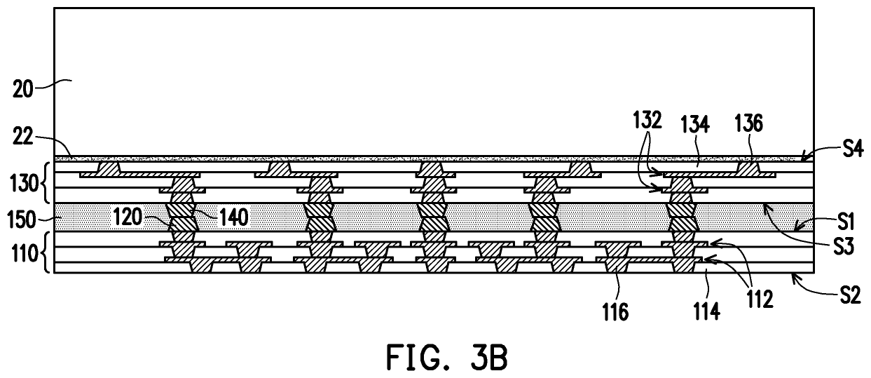

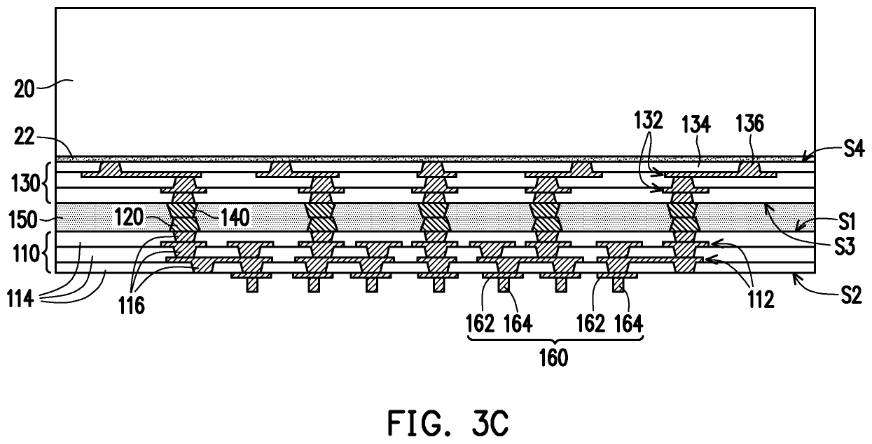

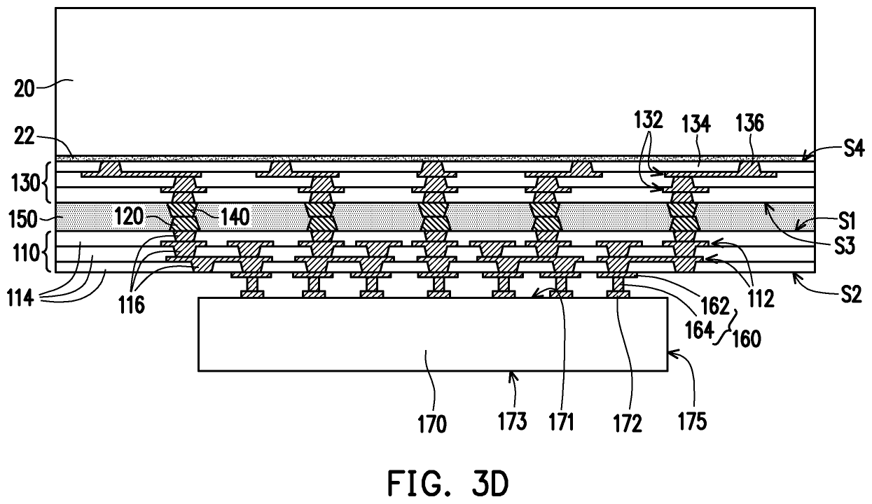

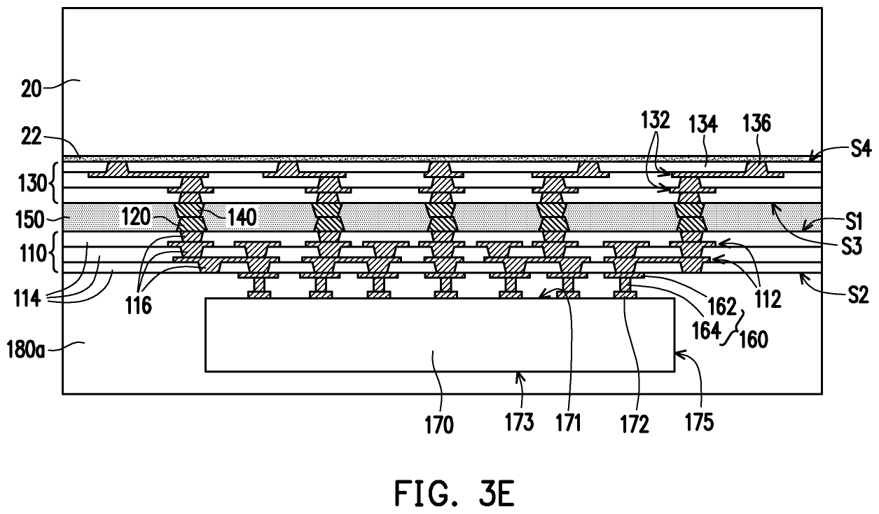

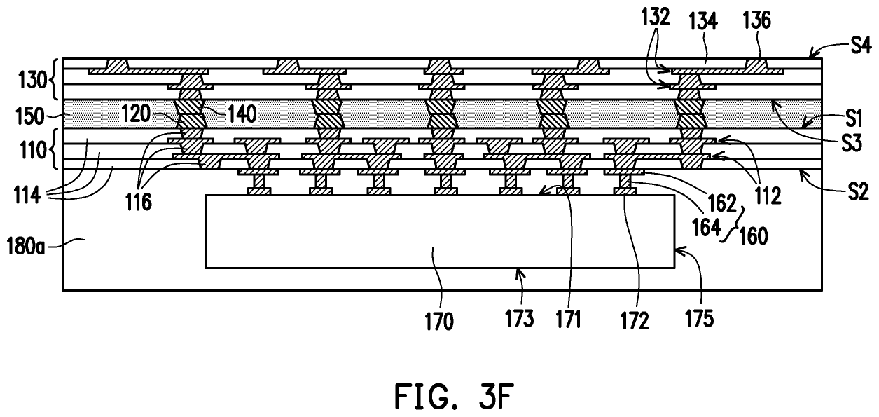

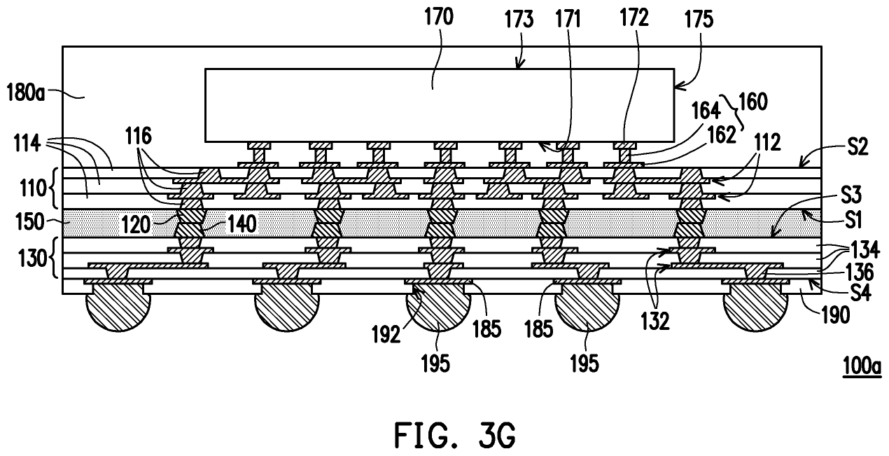

FIGS. 3A to 3G are schematic cross-sectional views of some steps of a manufacturing method of a semiconductor package structure according to an embodiment of the disclosure. The manufacturing method of the semiconductor package structure in this embodiment is similar to the manufacturing method of the above semiconductor substrate 10a. A difference between the two is that after the step in FIG. 1B, that is, after multiple second connecting members 140 are formed on the third surface S3 of the second thin film redistribution layer 130, referring to both FIGS. 1B and 3A, a filling glue layer 150 is filled between the first thin film redistribution layer 110 and the second thin film redistribution layer 130. The filling glue layer 150 covers the first connecting members 120 and the second connecting members 140 for protection. For example, a dispensing process of an underfill material may be performed, and then a curing process may be performed to form the filling glue layer 150. For example, the filling glue layer 150 is filled in a gap between the first surface S1 of the first thin film redistribution layer 110 and the third surface S3 of the second thin film redistribution layer 130 to surround, overlay, and, cover the first connecting members 120 and the second connecting members 140.

Referring to both FIGS. 3A and 3B, the first carrier 10 and the first release film 12 are removed, and the second surface S2 of the first thin film redistribution layer 110 is exposed. For example, by applying external energy (for example, heat and/or pressure, etc.) to the first release film 12 located between the first thin film redistribution layer 110 and the first carrier 10, the first release film 12 and the first film redistribution layer 110 are layered. Other suitable processes (for example, mechanical removing, etching, and grinding, etc.) may be used to remove the temporary first carrier 10 and the first release film 12. Optionally, a cleaning process is performed on the second surface S2 of the first thin film redistribution layer 110 to remove a residue of the first release film 12. A bottom surface of the first conductive via 116 that is flush with the lowermost first dielectric layer 114 on the second surface S2 may be exposed for further electrical connection after de-bonding.

Referring to FIG. 3C, multiple third connecting members 160 are formed on the second surface S2 of the first thin film redistribution layer 110. Each of the third connecting members 160 includes a pad 162 and a conductive pillar 164. The pads 162 are disposed on the second surface S2 of the first thin film redistribution layer 110, and are electrically connected to the first conductive vias 116. The conductive pillars 164 are respectively located on the pads 162, and the conductive pillars 164 are electrically connected to the first thin film redistribution layer 110 through the pads.

Referring to FIG. 3D, a chip 170 is disposed on the second surface S2 of the first thin film redistribution layer 110. The chip 170 has an active surface 171 and a back surface 173 opposite to each other, and a peripheral surface 175 connecting the active surface 171 and the back surface 173, and the chip 170 includes multiple fourth connecting members 172 disposed on the active surface 171. The fourth connecting members 172 of the chip 170 are respectively connected to the conductive pillars 164 of the third connecting members 160, so that the chip 170 is bonded to the first thin film redistribution layer 110. Here, the chip 170 is electrically connected to the first thin film redistribution layer 110 by flip chip bonding.

Referring to FIG. 3E, a molding compound 180a is formed to cover the third connecting members 160, the fourth connecting members 172, and the active surface 171, the back surface 173, and the peripheral surface 175 of the chip 170. That is to say, the molding compound 180a completely covers the chip 170, and an edge of the molding compound 180a is substantially flush with an edge of the filling glue layer 150, an edge of the first thin film redistribution layer 110, and an edge of the second thin film redistribution layer 130. However, the disclosure is not limited thereto.

Referring to both FIGS. 3E and 3F, the second carrier 20 and the second release film 22 are removed, and the fourth surface S4 of the second thin film redistribution layer 130 is exposed. That is to say, before the second carrier 20 and the second release film 22 are removed in this embodiment, the first carrier 10 and the first release film 12 have been removed, and the chip 170 has been disposed on the second surface S2 of the first thin film redistribution layer 110. Here, a method of removing the second carrier 20 and the second release film 22 is the same as that of removing the first carrier 10 and the first release film 12. Reference may be made to the method of removing the first carrier 10 and the first release film 12. Thus, details in this regard will not be further reiterated in the following.

Afterwards, referring to FIG. 3G, multiple connecting pads 185 separated from one another are formed on the fourth surface S4 of the second thin film redistribution layer 130. The connecting pads 185 are located on the outermost second dielectric layer 134, and are electrically connected to the second conductive vias 136 on an outermost side of the second thin film redistribution layer 130. Then, a solder mask layer 190 is formed on the fourth surface S4 of the second thin film redistribution layer 130. The solder mask layer 190 is located on the outermost second dielectric layer 134 and has multiple openings 192, so as to expose a part of each of the connecting pads 185.

Finally, referring to FIG. 3G again, multiple solder balls 195 is disposed on the fourth surface S4 of the second thin film redistribution layer 130. The solder balls 195 are respectively located in the openings 192 of the solder mask layer 190, and are structurally and electrically connected to the connecting pads 185 exposed by the openings 192. The chip 170 may be electrically connected to an external circuit (not shown) through the third connecting members 160, the first thin film redistribution layer 110, the first connecting members 120, the second connecting members 140, the second thin film redistribution layer 130, the connecting pads 185, and the solder balls 195 in sequence. After that, the overall structure is turned over and manufacture of a semiconductor package structure 100a has been completed.

It should be noted that in another embodiment which is not shown, before the first carrier 10 and the first release film 12 are removed, the second carrier 20 and the second release film 22 may be removed, and the connecting pads 185 and the solder balls 195 may be disposed on the fourth surface S4 of the second thin film redistribution layer 130, which still belongs to the scope of the disclosure.

In terms of the structure, referring to FIG. 3G again, the semiconductor package structure 100a in this embodiment includes the first thin film redistribution layer 110, the first connecting members 120, the second thin film redistribution layer 130, the second connecting members 140, the filling glue layer 150, the chip 170, and the solder balls 195. The first thin film redistribution layer 110 has the first surface S1 and the second surface S2 opposite to each other, and includes two layers of the first redistribution circuit layers 112, three layers of the first dielectric layers 114, and the first conductive vias 116. The first connecting members 120 are disposed on the first surface S1 of the first thin film redistribution layer 110. The second thin film redistribution layer 130 has the third surface S3 and the fourth surface S4 opposite to each other, and includes two layers of the second redistribution circuit layers 132, three layers of the second dielectric layers 134, and the second conductive vias 136. The second connecting members 140 are disposed on the third surface S3 of the second thin film redistribution layer 130. The second connecting members 140 are respectively connected to the first connecting members 120, so that the second thin film redistribution layer 130 is bonded to the first thin film redistribution layer 110. Herein, the number of layers of the first redistribution circuit layer 112 is the same as the number of layers of the second redistribution circuit layer 132, and the number of layers of the first dielectric layer 114 is the same as the number of layers of the second dielectric layer 134. However, the disclosure is not limited thereto. The filling glue layer 150 is filled between the first thin film redistribution layer 110 and the second thin film redistribution layer 130, and covers the first connecting members 120 and the second connecting members 140. The chip 170 is disposed on the second surface S2 of the first thin film redistribution layer 110. The solder balls 195 are disposed on the fourth surface S4 of the second thin film redistribution layer 130.

Furthermore, in this embodiment, the semiconductor package structure 100a further includes the third connecting members 160 disposed on the second surface S2 of the first thin film redistribution layer 110. The third connecting members 160 include the pads 162 and the conductive pillars 164. The chip 170 has the active surface 171 and the back surface 173 opposite to each other, and the peripheral surface 175 connecting the active surface 171 and the back surface 173, and the chip 170 includes the fourth connecting members 172 disposed on the active surface 171. The fourth connecting members 172 are respectively connected to the third connecting members 160, so that the chip 170 is bonded to the first thin film redistribution layer 110. The pads 162 are disposed on the second surface S2 of the first thin film redistribution layer 110, and the conductive pillars 164 are located between the pads 162 and the fourth connecting members 172 of the chip 170.

In addition, the semiconductor package structure 100a in this embodiment further includes the molding compound 180a covering the third connecting members 160, the fourth connecting members 172, and the active surface 171, the back surface 173, and the peripheral surface 175 of the chip 170. The edge of the molding compound 180a is flush with the edge of the filling glue layer 150. In addition, the semiconductor package structure 100a further includes the connecting pads 185 and the solder mask layer 190. The connecting pads 185 are disposed on the fourth surface S4 of the second thin film redistribution layer 130, and are structurally and electrically connected to the second conductive vias 136 on the outermost side of the second thin film redistribution layer 130. The solder mask layer 190 is disposed on the fourth surface S4 of the second thin film redistribution layer 130 and has the openings 192. The openings 192 expose a part of the connecting pads 185. The solder balls 195 are respectively located in the openings 192 of the solder mask layer 190, and are structurally and electrically connected to the connecting pads 185 exposed by the openings 192.

In brief, in a manufacturing method of the semiconductor package structure 100a in this embodiment, the second connecting members 140 located on the second thin film redistribution layer 130 are respectively connected to the first connecting members 120 located on the first thin film redistribution layer 110, so that the second thin film redistribution layer 130 is bonded to the first thin film redistribution layer 110. In this way, multilayer thin film redistribution layers with at least three or more layers are formed. Compared with the conventional thin film redistribution layer in which only the thin film redistribution layer with no more than three layers of circuits may be formed on a glass carrier, the manufacturing method of the semiconductor package structure 100a in this embodiment has an advantage of simple manufacturing process, and is not limited to the conventional technology in which only metal with two or three layers may be disposed on the glass carrier. Furthermore, in this embodiment, the first thin film redistribution layer 110 with the higher wiring density is bonded to the chip 170, and the second thin film redistribution layer 130 with the lower wiring density is bonded to the solder balls 195. In this way, a fan-out type circuit structure is formed. In addition, since the semiconductor package structure 100a in this embodiment may have the multilayer thin film redistribution layers with at least three or more layers, it may be applied and expanded to more complex systems.

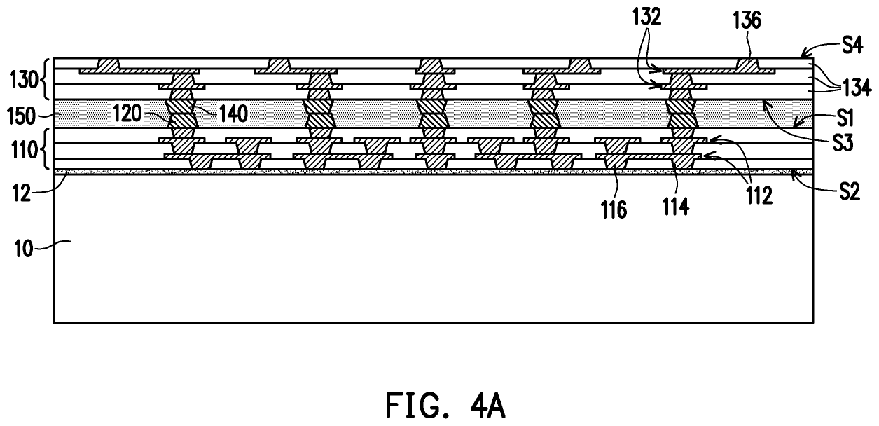

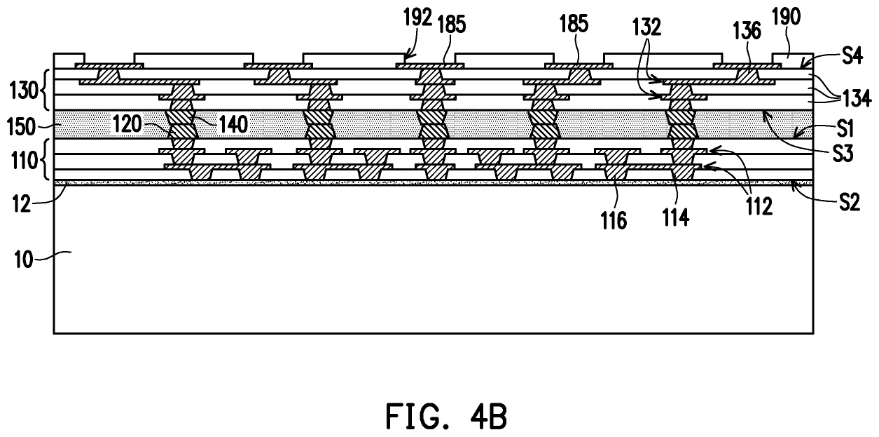

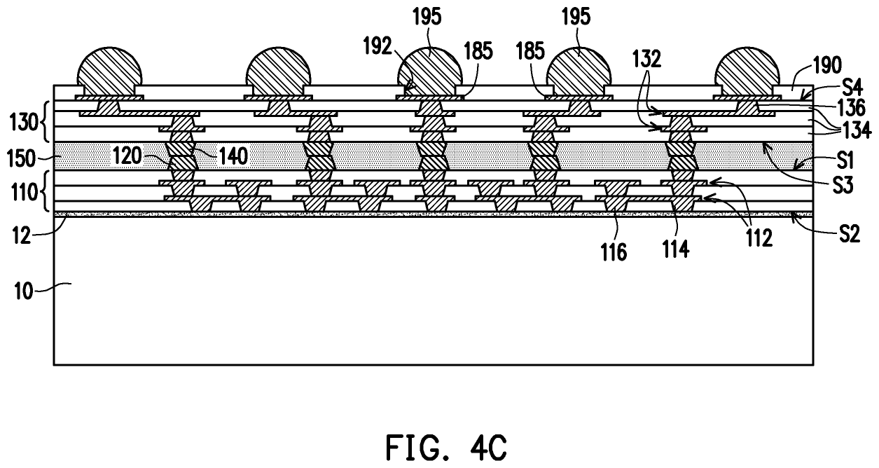

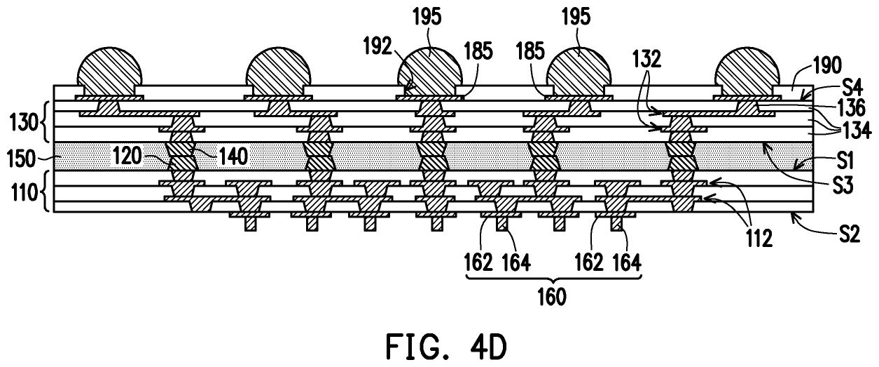

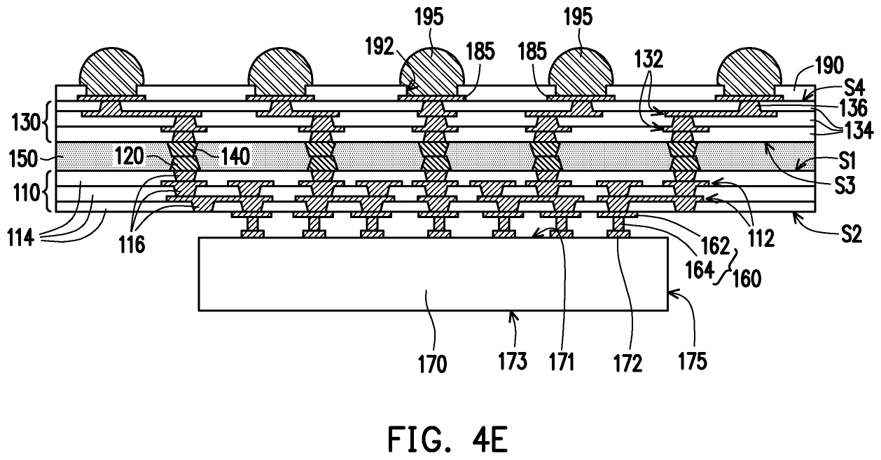

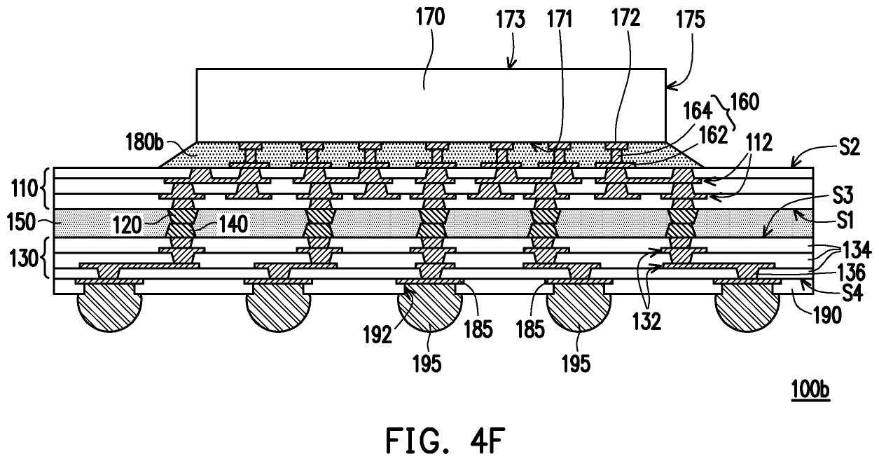

FIGS. 4A to 4F are schematic cross-sectional views of some steps of a manufacturing method of a semiconductor package structure according to another embodiment of the disclosure. The manufacturing method of the semiconductor package structure in this embodiment is similar to the manufacturing method of the above semiconductor package structure. A difference between the two is that after the step in FIG. 3A, that is, after the filling glue layer 150 is filled between the first thin film redistribution layer 110 and the second thin film redistribution layer 130, referring to both FIGS. 3A and 4A, the second carrier 20 and the second release film 22 are removed, and the fourth surface S4 of the second thin film redistribution layer 130 is exposed.

Referring to FIG. 4B, the connecting pads 185 separated from one another are formed on the fourth surface S4 of the second thin film redistribution layer 130. The connecting pads 185 are located on the outermost second dielectric layer 134 of the second thin film redistribution layer 130, and are electrically connected to the second conductive vias 136 on the outermost side of the second thin film redistribution layer 130.

Referring to FIG. 4B again, the solder mask layer 190 is formed on the fourth surface S4 of the second thin film redistribution layer 130. The solder mask layer 190 is located on the outermost second dielectric layer 134 of the second thin film redistribution layer 130, and the solder mask layer 190 has the openings 192 to expose a part of the connecting pads 185.

Referring to FIG. 4C, the solder balls 195 are disposed on the fourth surface S4 of the second thin film redistribution layer 130. The solder balls 195 are respectively located in the openings 192 of the solder mask layer 190, and are structurally and electrically connected to the connecting pads 185 exposed by the openings 192.

Referring to both FIGS. 4C and 4D, the first carrier 10 and the first release film 12 are removed, and the second surface S2 of the first thin film redistribution layer 110 is exposed. In other words, before the first carrier 10 and the first release film 12 are removed in this embodiment, the second carrier 20 and the second release film 22 have been removed, and the solder balls 195 have been disposed on the fourth surface S4 of the second thin film redistribution layer 130.

Referring to FIG. 4D again, the third connecting members 160 are formed on the second surface S2 of the first thin film redistribution layer 110. The third connecting members 160 include the pads 162 and the conductive pillars 164. The pads 162 are disposed on the second surface S2 of the first thin film redistribution layer 110, and the conductive pillars 164 are located on the pads 162.

Afterwards, Referring to FIG. 4E, the chip 170 is disposed on the second surface S2 of the first thin film redistribution layer 110. The fourth connecting members 172 of the chip 170 are respectively connected to the conductive pillars 164 of the third connecting members 160, so that the chip 170 is bonded to the first thin film redistribution layer 110. Here, the chip 170 is electrically connected to the first thin film redistribution layer 110 by flip chip bonding.

Finally, referring to FIG. 4F, an underfill 180b is formed to cover the third connecting members 160, the fourth connecting members 172, and the active surface 171 of the chip 170. The underfill 180b exposes the back surface 173 and the peripheral surface 175 of the chip 170, which may have a better heat dissipation effect. Here, a material of the underfill 180b may be the same as or different from a material of the filling glue layer 150, and the disclosure is not limited thereto. After that, the overall structure is turned over and manufacture of a semiconductor package structure 100b has been completed.

It should be noted that in another embodiment which is not shown, before the second carrier 20 and the second release film 22 are removed, the first carrier 10 and the first release film 12 may be removed; the chip 170 may be disposed on the second surface S2 of the first thin film redistribution layer 110, and the underfill 180b nay be formed, which still belongs to the scope of the disclosure.

In terms of the structure, referring to both FIGS. 3G and 4F, the semiconductor package structure 100b in this embodiment is similar to the semiconductor package structure 100a in FIG. 3G. A difference between the two is that in this embodiment, the molding compound 180a is not used, while the underfill 180b is used. In detail, the underfill 180b covers the third connecting members 160, the fourth connecting members 172, and the active surface 171 of the chip 170, and exposes the back surface 173 and the peripheral surface 175 of the chip 170. Since the underfill 180b does not completely cover the chip 170, the semiconductor package structure 100b in this embodiment may have the better heat dissipation effect.

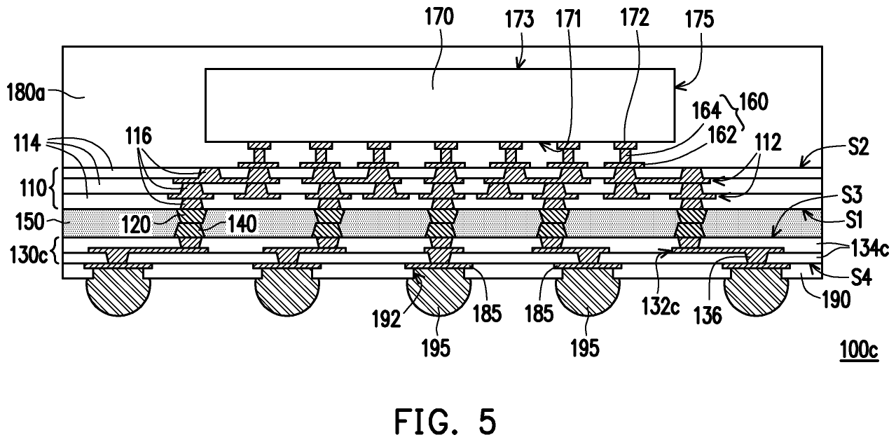

FIG. 5 is a schematic cross-sectional view of a semiconductor package structure according to an embodiment of the disclosure. Referring to both FIGS. 3G and 5, a semiconductor package structure 100c in this embodiment is similar to the semiconductor package structure 100a in FIG. 3G. A difference between the two is that in this embodiment, the number of layers of the first thin film redistribution layer 110 is different from that of a second thin film redistribution layer 130c. In detail, the first thin film redistribution layer 110 in this embodiment includes two layers of the first redistribution circuit layers 112 and three layers of the first dielectric layers 114, and the second thin film redistribution layer 130c includes one layer of a second redistribution circuit layer 132c and two layers of second dielectric layers 134c. In other words, the number of layers of the first thin film redistribution layer 110 and that of the second thin film redistribution layer 130c are not symmetrical. Herein, after the second thin film redistribution layer 130c is bonded to the first thin film redistribution layer 110, the multilayer thin film redistribution layers with at least three or more layers may be formed, which may be applied and extended to more complex systems.

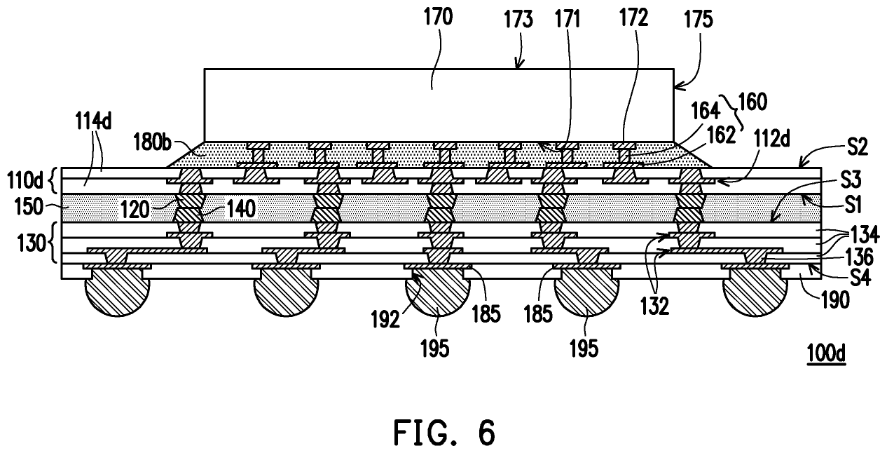

FIG. 6 is a schematic cross-sectional view of a semiconductor package structure according to another embodiment of the disclosure. Referring to both FIGS. 4F and 6, a semiconductor package structure 100d in this embodiment is similar to the semiconductor package structure 100b in FIG. 4F. A difference between the two is that in this embodiment, the number of layers of a first thin film redistribution layer 110d is different from that of the second thin film redistribution layer 130. In detail, the first thin film redistribution layer 110d in this embodiment includes one layer of a first redistribution circuit layer 112d and two layers of first dielectric layers 114d, and the second thin film redistribution layer 130 includes two layers of the second redistribution circuit layers 132 and three layers of the second dielectric layers 134c. In other words, the number of layers of the first thin film redistribution layer 110d and that of the second thin film redistribution layer 130 are not symmetrical. Herein, after the second thin film redistribution layer 130 is bonded to the first thin film redistribution layer 110d, the multilayer thin film redistribution layers with at least three or more layers may be formed, which may be applied and extended to more complex systems.

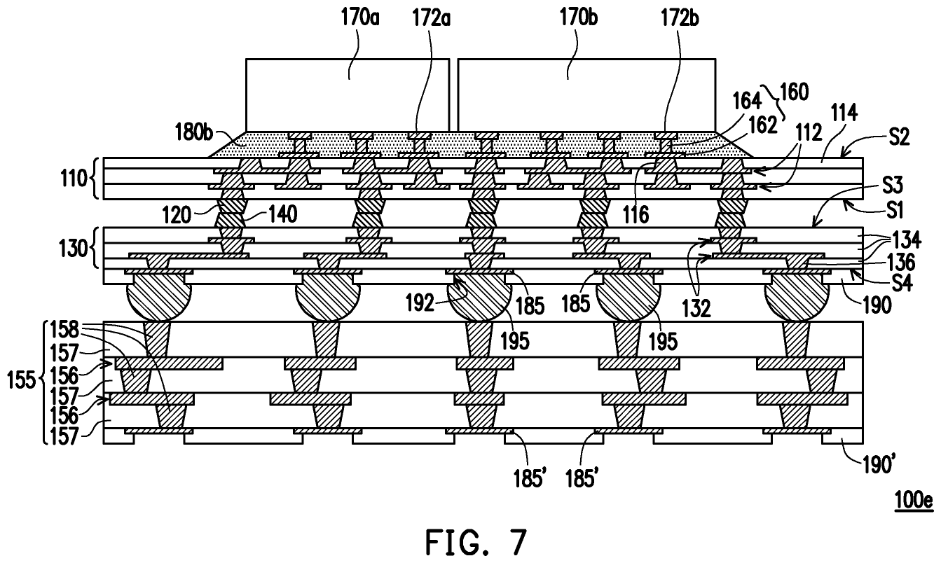

FIG. 7 is a schematic cross-sectional view of a semiconductor package structure according to another embodiment of the disclosure. Referring to both FIGS. 6 and 7, a semiconductor package structure 100e in this embodiment is similar to the semiconductor package structure 100d in FIG. 6. A difference between the two is that in this embodiment, the semiconductor package structure 100e includes the semiconductor substrate 10b of FIG. 2 and a chip 170a and a chip 170b are disposed on the second surface S2 of the first thin film redistribution layer 110. The fourth connecting members 172a, 172b of the chip 170a, 170b are respectively connected to the conductive pillars 164 of the third connecting members 160, so that the chip 170a, 170b are bonded to the first thin film redistribution layer 110d. Herein, the chip 170a, 170b are electrically connected to the first thin film redistribution layer 110d by flip chip bonding. Optionally, the connection between the first connecting members 120 and the second connecting members 140 can be solder bonding, hybrid boning or copper to copper direct bonding, and the disclosure is not limited thereto. Optionally, the redistribution structure layer 155 with the lower wiring density is bonded to the solder balls.

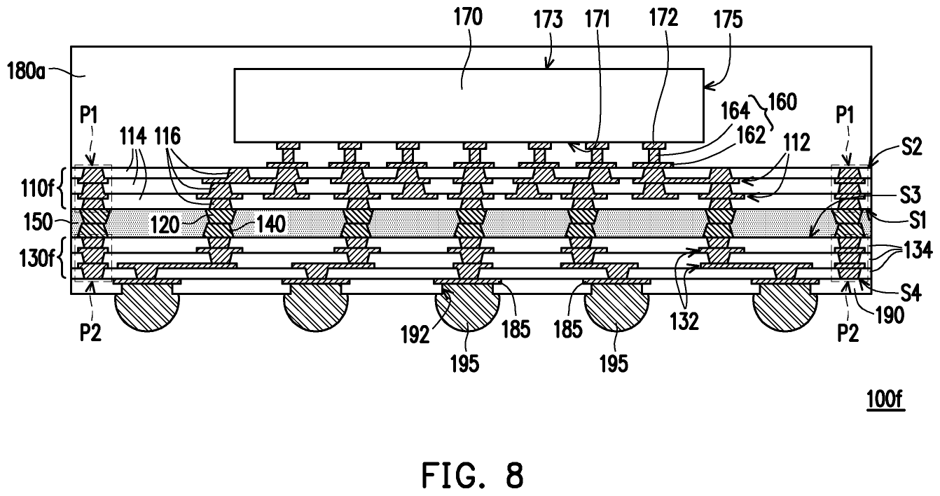

FIG. 8 is a schematic cross-sectional view of a semiconductor package structure according to another embodiment of the disclosure. Referring to both FIGS. 3G and 8, a semiconductor package structure 100f in this embodiment is similar to the semiconductor package structure 100a in FIG. 3G. A difference between the two is that in this embodiment, a first thin film redistribution layer 110f further includes a first retaining ring P1 surrounding the first redistribution circuit layers 112, and a second thin film redistribution layer 130f further includes a second retaining ring P2 surrounding the second redistribution circuit layers 132. The first retaining ring P1 and the second retaining ring P2 are connected to each other through the first connecting members 120 and the second connecting members 140. Here, in addition to serving as support to increase the overall structural strength, the first retaining ring P1 and the second retaining ring P2 may also be used as an alignment mark or a grounding ring. In addition, the mostly pad pitch of the second surface S2 of the first thin film redistribution layer 110f is finer than the mostly pad pitch of the fourth surface S4 of the second thin film redistribution layer 130f. Optionally, the connection between the first connecting members 120 and the second connecting members 140 can be solder bonding, hybrid boning or copper to copper direct bonding, and the disclosure is not limited thereto. The solder balls 195 on the connecting pads 185 are optional.

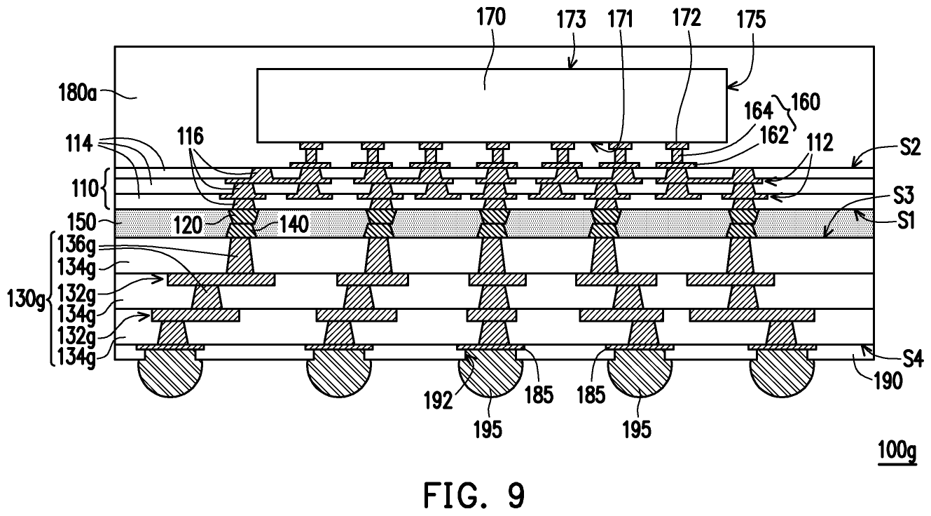

FIG. 9 is a schematic cross-sectional view of a semiconductor package structure according to another embodiment of the disclosure. Referring to both FIGS. 3G and 9, a semiconductor package structure 100g in this embodiment is similar to the semiconductor package structure 100a of FIG. 3G. A difference between the two is that in this embodiment, a thickness of each of second dielectric layers 134g is greater than a thickness of each of the first dielectric layers 114, and a material of the second dielectric layer 134g is, for example, prepreg (PP) or Ajinomoto build up film (ABF). However, the disclosure is not limited thereto. The wiring density of the first thin film redistribution layer 110 is higher than a wiring density of the second thin film redistribution layer 130g, and a line width and a line pitch of a second redistribution circuit layer 132g are greater than a line width and a line pitch of the first redistribution circuit layer 112. Optionally, the connection between the first connecting members 120 and the second connecting members 140 can be solder bonding, hybrid boning or copper to copper direct bonding, and the disclosure is not limited thereto. The solder balls 195 on the connecting pads 185 are optional.

It should be noted that if the number of first thin film redistribution layer and the second thin film redistribution layer count are similar. That is, either they have the same number of layer counts or their layer count difference is “One”. The first thin film redistribution layer and the second thin film redistribution layer will have similar internal stress. Furthermore, since one thin film layer unit rotates 180 degrees during assembly, the assembled thin film layer internal stress is minimized by offsetting each other. Hence the warpage of the formed thin film layer is also significantly reduced. Another virtue of this invention is that before assembling IC chips, the semiconductor substrate may be tested to guarantee electrical connection and evaluation of qualify. Besides, the semiconductor substrate could be used as a space transformer in the advanced semiconductor testing.

Based on the above, in the design of the semiconductor package structure in the disclosure, the second connecting members located on the second thin film redistribution layer are respectively connected to the first connecting members located on the first thin film redistribution layer, so that the second thin film redistribution layer is bonded to the first thin film redistribution layer. In this way, the multilayer thin film redistribution layers with at least three or more layers may be formed, and the manufacturing process is simple.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A semiconductor substrate, comprising:
a first thin film redistribution layer having a first surface and a second surface opposite to each other;
a plurality of first connecting members disposed on the first surface of the first thin film redistribution layer;
a second thin film redistribution layer having a third surface and a fourth surface opposite to each other; and
a plurality of second connecting members disposed on the third surface of the second thin film redistribution layer, wherein the second connecting members are respectively connected to the first connecting members, so that the second thin film redistribution layer is bonded to the first thin film redistribution layer.

2. The semiconductor substrate according to claim 1, further comprising:
a filling glue layer filled between the first thin film redistribution layer and the second thin film redistribution layer, and covering the first connecting members and the second connecting members.

3. The semiconductor substrate according to claim 1, wherein a number of layers of the first thin film redistribution layer is close to a number of layers of the second thin film redistribution layer, and the number of layers of the first thin film redistribution layer is one layer more than the number of layers of the second thin film redistribution layer.

4. The semiconductor substrate according to claim 1, wherein a number of layers of the first thin film redistribution layer is the same as a number of layers of the second thin film redistribution layer.

5. The semiconductor substrate according to claim 1, wherein a coefficient of thermal expansion of the first thin film redistribution layer is the same as or similar to a coefficient of thermal expansion of the second thin film redistribution layer.

6. The semiconductor substrate according to claim 1, further comprising:
a plurality of connecting pads disposed separately from one another on the fourth surface of the second thin film redistribution layer and electrically connected to the second thin film redistribution layer; and
a solder mask layer disposed on the fourth surface of the second thin film redistribution layer and having a plurality of openings, wherein the openings expose a part of the connecting pads.

7. The semiconductor substrate according to claim 1, wherein the first thin film redistribution layer comprises a plurality of first conductive vias, and the second thin film redistribution layer comprises a plurality of second conductive vias, a via tapered direction of each of the first conductive vias is in opposite direction of a via tapered direction of each of the second conductive vias.

8. The semiconductor substrate according to claim 1, wherein a wiring density of the first thin film redistribution layer is higher than a wiring density of the second thin film redistribution layer.

9. The semiconductor substrate according to claim 1, wherein the first thin film redistribution layer comprises multilayer first redistribution circuit layers and a first retaining ring surrounding the first redistribution circuit layers, the second thin film redistribution layer comprises multilayer second redistribution circuit layers and a second retaining ring surrounding the second redistribution circuit layers, and the first retaining ring and the second retaining ring are connected to each other through the first connecting members and the second connecting members.

10. The semiconductor substrate according to claim 1, wherein the mostly pad pitch of the second surface of the first thin film redistribution layer is finer than the mostly pad pitch of the fourth surface of the second thin film redistribution layer.

11. A manufacturing method of a semiconductor substrate, comprising:
forming a first thin film redistribution layer on a first carrier, wherein a first release film is disposed on the first carrier, the first thin film redistribution layer has a first surface and a second surface opposite to each other, and the first release film is located between the second surface of the first thin film redistribution layer and the first carrier;
forming a plurality of first connecting members on the first surface of the first thin film redistribution layer;
forming a second thin film redistribution layer on a second carrier, wherein a second release film is disposed on the second carrier, the second thin film redistribution layer has a third surface and a fourth surface opposite to each other, and the second release film is located between the fourth surface of the second thin film redistribution layer and the second carrier;
forming a plurality of second connecting members on the third surface of the second thin film redistribution layer;
respectively connecting the second connecting members to the first connecting members, so that the second thin film redistribution layer is bonded to the first thin film redistribution layer;
removing the first carrier and the first release film, and exposing the second surface of the first thin film redistribution layer; and
removing the second carrier and the second release film, and exposing the fourth surface of the second thin film redistribution layer.

12. The manufacturing method of the semiconductor substrate according to claim 11, further comprising:
after removing the second carrier and the second release film, forming a plurality of connecting pads separated from one another on the fourth surface of the second thin film redistribution layer, wherein the connecting pads are electrically connected to the second thin film redistribution layer; and
forming a solder mask layer on the fourth surface of the second thin film redistribution layer, wherein the solder mask layer has a plurality of openings to expose a part of the connecting pads.

13. The manufacturing method of the semiconductor substrate according to claim 11, wherein a number of layers of the first thin film redistribution layer is different from a number of layers of the second thin film redistribution layer, and the number of layers of the first thin film redistribution layer is one layer more than the number of layers of the second thin film redistribution layer.

14. The manufacturing method of the semiconductor substrate according to claim 11, wherein a number of layers of the first thin film redistribution layer is the same as a number of layers of the second thin film redistribution layer.

15. The manufacturing method of the semiconductor substrate according to claim 11, wherein the first thin film redistribution layer comprises a plurality of first conductive vias, and the second thin film redistribution layer comprises a plurality of second conductive vias, a via tapered direction of each of the first conductive vias is in opposite direction of a via tapered direction of each of the second conductive vias.

16. The manufacturing method of the semiconductor substrate according to claim 11, wherein a wiring density of the first thin film redistribution layer is higher than a wiring density of the second thin film redistribution layer.

17. The manufacturing method of the semiconductor substrate according to claim 11, wherein the first thin film redistribution layer comprises multilayer first redistribution circuit layers and a first retaining ring surrounding the first redistribution circuit layers, the second thin film redistribution layer comprises multilayer second redistribution circuit layers and a second retaining ring surrounding the second redistribution circuit layers, and the first retaining ring and the second retaining ring are connected to each other through the first connecting members and the second connecting members.

18. A semiconductor package structure, comprising:
a first thin film redistribution layer having a first surface and a second surface opposite to each other;
a plurality of first connecting members disposed on the first surface of the first thin film redistribution layer;
a second thin film redistribution layer having a third surface and a fourth surface opposite to each other;
a plurality of second connecting members disposed on the third surface of the second thin film redistribution layer, wherein the second connecting members are respectively connected to the first connecting members, so that the second thin film redistribution layer is bonded to the first thin film redistribution layer;
a chip disposed on the second surface of the first thin film redistribution layer; and
a plurality of solder balls disposed on the fourth surface of the second thin film redistribution layer.

19. The semiconductor package structure according to claim 18, further comprising:
a filling glue layer filled between the first thin film redistribution layer and the second thin film redistribution layer, and covering the first connecting members and the second connecting members.

20. The semiconductor package structure according to claim 18, further comprising:
a plurality of third connecting members disposed on the second surface of the first thin film redistribution layer, wherein the chip has an active surface and a back surface opposite to each other, and a peripheral surface connecting the active surface and the back surface, and the chip comprises a plurality of fourth connecting members disposed on the active surface, wherein the fourth connecting members are respectively connected to the third connecting members, so that the chip is bonded to the first thin film redistribution layer.

21. The semiconductor package structure according to claim 20, wherein each of the third connecting members comprises a pad and a conductive pillar, the pad is disposed on the second surface of the first thin film redistribution layer, and the conductive pillar is located between the pad and each of the fourth connecting members of the chip.

22. The semiconductor package structure according to claim 20, further comprising:
a molding compound covering the third connecting members, the fourth connecting members, and the active surface, the back surface, and the peripheral surface of the chip, wherein an edge of the molding compound is flush with an edge of the filling glue layer.

23. The semiconductor package structure according to claim 20, further comprising:
an underfill covering the third connecting members, the fourth connecting members, and the active surface of the chip, and exposing the back surface and the peripheral surface of the chip.

24. The semiconductor package structure according to claim 18, wherein a number of layers of the first thin film redistribution layer is different from a number of layers of the second thin film redistribution layer.

25. The semiconductor package structure according to claim 18, wherein a number of layers of the first thin film redistribution layer is the same as a number of layers of the second thin film redistribution layer.

26. The semiconductor package structure according to claim 18, wherein the semiconductor substrate further comprises:
a plurality of connecting pads disposed separately from one another on the fourth surface of the second thin film redistribution layer and electrically connected to the second thin film redistribution layer; and
a solder mask layer disposed on the fourth surface of the second thin film redistribution layer and having a plurality of openings, wherein the openings expose a part of the connecting pads, and the solder balls are respectively located in the openings and connected to the connecting pads exposed by the openings.

27. The semiconductor package structure according to claim 18, wherein an extending direction of each of the first connecting members is opposite to an extending direction of each of the second connecting members.

28. The semiconductor package structure according to claim 18, wherein a wiring density of the first thin film redistribution layer is higher than a wiring density of the second thin film redistribution layer.

29. The semiconductor package structure according to claim 18, wherein the first thin film redistribution layer comprises multilayer first redistribution circuit layers and a first retaining ring surrounding the first redistribution circuit layers, the second thin film redistribution layer comprises multilayer second redistribution circuit layers and a second retaining ring surrounding the second redistribution circuit layers, and the first retaining ring and the second retaining ring are connected to each other through the first connecting members and the second connecting members.
